(19) United States
(12) Patent Application Publication
(10) Pub. No.: US 2008/0117675 A1
(43) Pub. Date: May 22, 2008

(54) Reducing read disturb in non-volatile multiple- level cell memories

(76) Inventors: Rezaul Haque, Folsom, CA (US); Kerry D. Tedrow, Folsom, CA (US)

Correspondence Address: TROP PRUNER & HU, PC, 1616 S. VOSS ROAD, SUITE 750, HOUSTON, TX, 77057-2631, US

(21) Appl. No.: 11/601,392

(22) Filed: Nov. 17, 2006

(51) Int. Cl. G11C 16/04; G11C 16/06

(52) U.S. Cl. 365/185.03; 365/185.18

(57) ABSTRACT

The supply voltage to a selected cell may be turned off after sensing. In one embodiment, this may be done by providing the output of the sense amplifier through a control circuit to simply turn off the voltage to the selected column or bitline. This may reduce the drain disturb by reducing the amount of voltage applied over time to a multi-level cell.

### BACKGROUND

This relates generally to non-volatile multiple-level cell memories.

In a flash memory, stored charge is maintained on the floating gate of a memory cell. A large number of such cells may be used to retain a large amount of information.

The voltage between the drain and the source of the flash cell is kept above some minimum value to ensure that the current gain through the flash cell is high enough to meet the overall requirements of a read window. At the other extreme, the voltage between the drain and source of the flash cell is kept below some maximum value to avoid the stored charge on the floating gate being disturbed during a read. If the voltage of the drain gets too high when the cell is being read, additional charge can accumulate on the floating gate, invalidating already stored data.

The information stored per cell may be increased by using so-called multiple-level cells. These multiple-level cells may store numerous pieces of information in the same cell. This may be done by providing different levels within the cell. Each of the levels may be associated with a different threshold voltage so that, depending on the voltage applied to the cell, a particular level may be read.

Multiple-level memories are often flash memories, but other non-volatile memory technologies may use the multiple-levels as well.

### BRIEF DESCRIPTION OF THE DRAWINGS

FIG. 1 is a schematic depiction of one embodiment;

FIG. 2 is a timing diagram for a sense sequence and sense cycle in accordance with one embodiment of the present invention; and

FIG. 3 is a system depiction for one embodiment of the present invention.

### DETAILED DESCRIPTION

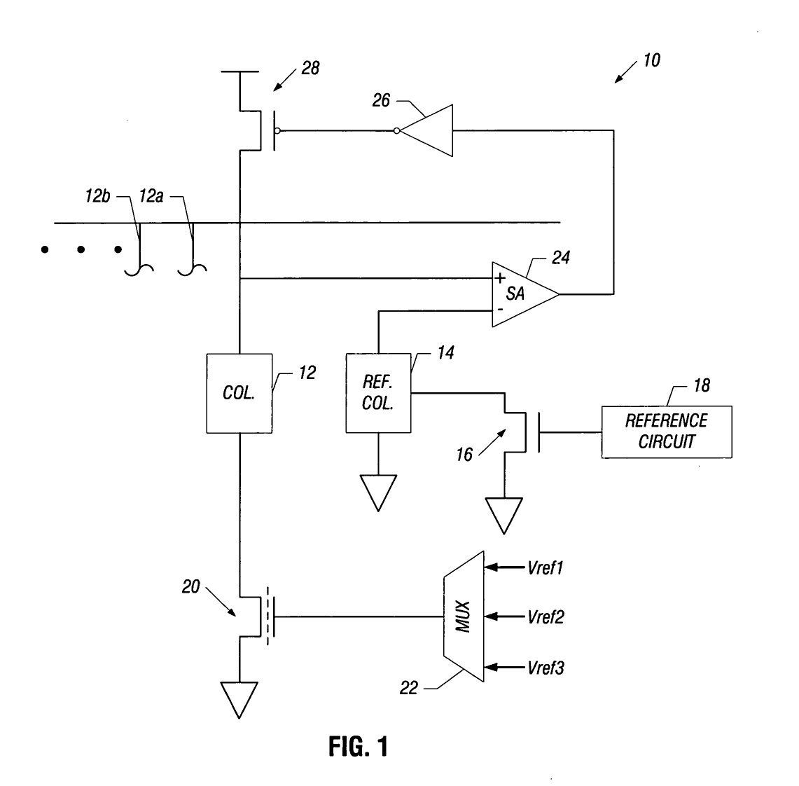

Referring to FIG. 1, a multi-level cell memory device 10 includes a memory array represented by a single memory cell 20, a multiplexer 22 coupled to the gate of cells 20 and a column 12 coupled to the drain of cells 20. A transistor 28 supplies current to the column. A common node 30 for a plurality of columns receives a column supply voltage. A sense amplifier 24 is coupled to the gate of the transistor 28 through an inverter 26, and a reference column 14. The reference column may be identical to the column 12 and may be coupled through a current mirror transistor 16 to a reference cell included within a reference circuit 18.

Thus, at a high level, the current flowing through the memory cell 20, as a result of one of three reference voltages applied to its gate, is detected at the non-inverting input to the sense amplifier 24. The inverting input is connected to a current developed through a reference circuit 18 and a reference column 14.

The output of the sense amplifier 24 is inverted and used to drive the gate of a P-channel transistor 28 coupled to a supply voltage on its source. As a result of the operation of the inverter 26 and the transistor 28, an automatic feedback, drain voltage reduction scheme reduces the drain disturb condition, enabling the device 10 to cycle successfully over different usage models. As process technologies continue to shrink, the drain disturb condition becomes more and more of a problem, particularly for multi-level memories. Drain disturb may be reduced by simply reducing the voltage to the column and, thus, the drain of the cell, after sensing.

In the case of a multiple-level memory cell, the cell may be exposed to a series of increasing voltages. A cell at one particular level may be exposed to the voltages applied to trip the higher voltage level or threshold voltage detecting states of the cell. These higher voltages may be too high for the lower threshold voltage, creating what is called a read disturb. A read disturb may occur in a flash memory when the voltage applied to the cell is high enough that it actually supplies additional charge to its floating gate, creating an improper state. In effect, a read disturb is a result of an attempt to read the cell that actually reprograms the cell.

If that cell's word line voltage level were reduced after sensing its state during a read operation, the cell would not be affected as significantly by subsequent voltages applied to sense higher threshold level states. This is because the cell would be exposed to less voltage over time.

A large number of such cells may be connected to additional columns 12a, 12b, etc. In addition, while only one cell and, effectively, one row is depicted, conventional non-volatile memories have many rows, many columns, and blocks of memory cells all coupled together.

The memory array represented by the single cell 20 includes a multi-level flash memory cell having its gate node coupled to a word line 21. However, other non-volatile multiple-level memory cells may be used as well including, as one example, an ovonic memory cell. The cell 20 is capable of storing multiple bits of information, each level programmed to have a different threshold voltage level. In the case of a flash memory, the threshold voltage of the programmed cell depends in part on the amount of charge stored on its floating gate. By varying the amount of charge stored, a flash memory cell may be programmed to one of a plurality of levels.

For example, the cell 20 may be programmed to one of four levels to effectively store two bits of information in the memory cell. Although this description focuses on an embodiment in which each multi-level cell is programmed to one of four levels, the various embodiments of the invention are not so limited. For example, in some embodiments, each multi-level cell may be programmed to one of eight levels, or one of sixteen levels, to mention two other examples.

In operation, the cell state may be determined by performing multiple comparisons of the cell drain current to a fixed reference current, where the cell gate voltage is varied for each comparison. For an N-state memory, N−1 comparisons with N−1 gate voltage values may be used to uniquely determine the cell state.

Stepped voltage generator 22 sources the N−1 gate voltage values, where N is equal to four in this example. The N−1 gate voltage values may be fixed and generated using a non-chip voltage reference circuit (not shown), which may be independent of environmental conditions in some embodiments. The multiplexer 22 selects one of the N−1 gate voltage values to be applied to the word line 21. In some embodiments, the gate voltage sequence is from high values to low values (step down). In other embodiments, the gate voltage sequence is from low to high (step up). In still further embodiments, the sequence of gate voltages may be arbitrary. For example, for a multi-level cell having four possible states, the gate may be driven with three voltage values in sequence, starting with the center value, then proceeding to the low value, and then the high value.

Sense amplifiers 24 compare currents in the array of cells to a reference current. For example, the sense amplifier 24 may compare a drain current through the cell 20 to a drain current in a reference cell included within the reference circuit 18. The output of the sense amplifier 24 is a digital signal representing the result of the comparison. This comparison result may be converted to a binary representation of the cell state by logically combining the comparison result with a digital count that represents the cell state being compared against. Various methods may be used to perform this state determination.

For program and erase operations, it may be desirable to position the cell levels halfway between the state values used for read. This may provide high reliability for subsequent read operations in some embodiments. The state position may be accomplished by incorporating a special read mode, called verify mode, into the program and erase operations. This mode may be used to verify the cell state is correctly positioned. The verify mode gate voltage values may be intentionally offset from the read mode values to achieve the desired state positioning. It may also be desirable for the verify mode to use the same gate voltage timing and sequences used during the read mode so that transient offsets in the gate path may be common to both verify and read, thus being canceled.

In some embodiments, the reference circuit 18 may use a reference cell (not shown) that may be identical to the array cells 20. The threshold voltage value of the reference cell may be adjusted during manufacturing and testing to achieve a desired nominal reference current. The gate voltage of the reference cell may be ideal and, particularly, may be independent of environmental conditions. In some embodiments, a separate reference current generator may be provided for each sense amplifier. A current mirror 16 may be used to propagate the current of a single reference cell to the sense amplifier 24.

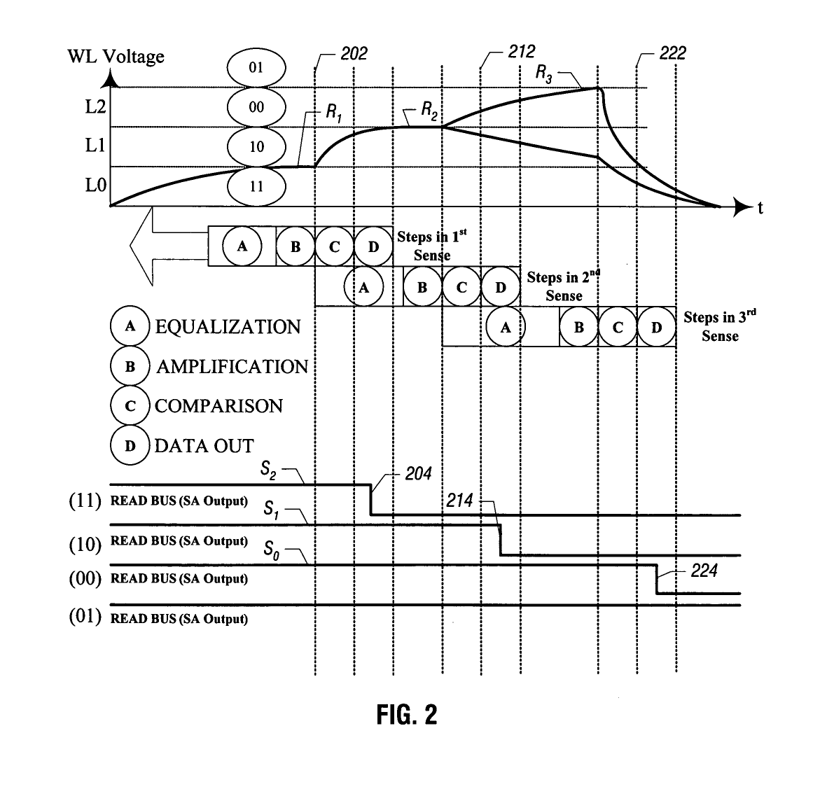

FIG. 2 shows waveforms corresponding to the read cycle of the memory device of FIG. 1. The four levels, L0, L1, L2, and L3 represent the four possible states of the memory cell in this example. The outputs S0, S1, and S2 of the sense amplifiers are placed at a known state at the beginning of any sense operation. In embodiments represented by FIG. 2, the gate voltage of the memory cell steps up through different cell levels to reference voltage values indicated as R1, R2, and R3.

As the word line voltage ramps up, the state of the sense amplifier output changes at a point based on the threshold voltage of the cell being sensed. The point at which the sense amplifier output changes state is referred to as the “sense amplifier trip point.” The gate voltage steps are synchronized.

As the word line voltage is stepped up through the multiplexer 22, S2 trips at 204, as a result of the sense operation at 202, S1 trips at 214, as a result of the sense operation at 212, and then S3 trips, as a result of the sense operation at 22. A sense amplifier that is coupled to a cell in the initialized state of 01 does not trip corresponding the last level L3. In some embodiments, the sense amplifier samples differential outputs at three different points. After the bitlines are sampled, the word line can start changing to the next level. The sense amplifier is isolated from the memory cells, the sensing operation can complete in parallel with word line change for the next step. The background sensing while the word line is ramping up may improve speed and performance.

Cells programmed at the R1 level and erased cells would be most susceptible to drain disturb conditions due to higher current flowing through the flash cell while the word line is being ramped up through the different levels to complete one sense operation. In multi-level cell sense operations, the word line may be changed to three different levels and, based on the cell's threshold voltage, the sense amplifier either changes its output or keeps a predefined output. For example, as the word line is being ramped up from ground to R1, and then to R2, and finally to R3, the read bus is the output of the sense amplifier.

For an erased flash cell, the read bus switches to ground from the supply voltage after the first sense. For a level 1 programmed cell, the read bus flips to ground after the second sense, and for a level 2 programmed cell, the read bus trips to 0 after third sense. For a cell programmed to level 3, the read bus does not trip at all.

Thus, a multi-level sense cycle may include three separate sense operations at three different word line voltage levels. The drain voltage of the cells, set to the required drain voltage determined to meet boundary conditions, usually remains high during the entire sense cycle. That is, as mentioned earlier, the drain and source of the flash cell may be kept above some minimum value to ensure that the current gain through the cell is high enough to meet the overall requirements of the read window.

By shutting down, or at least reducing, the drain voltage to ground as soon as the data is sensed in any sense operation within the sense cell, the drain disturb can be reduced in one embodiment. This may reduce the exposure of the level 1 cell to high drain voltage through the entire sensed cycle time, which comprises the time required to complete three separate sense operations, as described previously.

The sense amplifier 24 output may be used to shutdown the supply voltage to the entire sensed path. Since the cell 20 is coupled to the selected word line 21, which removes powered-up after the power to the selected bitline is reduced, the gate of the cell 20 sees the word line ramping up through three different levels, thus allowing it to conduct current to lower the drain voltage below the point where it would cause a read disturb condition. Thus, the cell works as a discharge path for the storage charge on the bitline or column 12.

In some embodiments, this technique may be implemented without requiring any special pull down devices and could produce virtually no impact on die area. The output of the sense amplifier may be pre-charged high in a default condition and, thus, any added devices in the sense amplifier would not impact the default time of pre-charge and equalization of the sensed critical nodes.

By grounding a selected cell bitline after the sense amplifier is tripped, read disturb may be reduced in a multi-path, multi-level cell read scheme. A reduction in drain disturb may be equivalent to lowering the target drain voltage, giving a way to get the read disturb benefit of lower drain voltage without the drawbacks of other potential approaches.

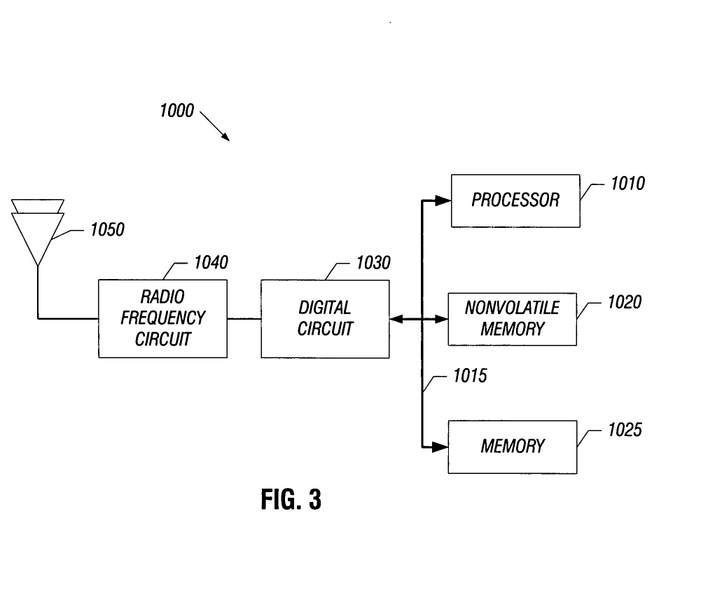

FIG. 3 shows an electronic system in accordance with various embodiments of the present invention. Electronic system 1000 includes processor 1010, non-volatile memory 1020, memory 1025, digital circuit 1030, radio frequency (RF) circuit 1040, and antennas 1050. Processor 1010 may be any type of processor adapted to access non-volatile memory 1020 and memory 1025. For example, processor 1010 may be a microprocessor, a digital signal processor, a microcontroller, or the like.

Example systems represented by FIG. 3 include cellular phones, personal digital assistant, wireless local area network interfaces, or any other suitable system. Non-volatile memory 1020 may be adapted to hold information for system 1000. For example, non-volatile memory 1020 may hold device configuration data, such as contact information with phone numbers, or settings for digital circuit 1030 or RF circuit 1040. Further, non-volatile memory 1020 may hold multimedia files such as photographs or music files. Still further, non-volatile memory 1020 may hold program code to be executed by processor 1010. Non-volatile memory 1020 may be any of the memory embodiments described herein, including memory device 10 (FIG. 1). Many other systems uses for non-volatile memory 1020 exist. For example, non-volatile memory 1020 may be used in a desktop computer, a network bridge or router, or any other system without an antenna.

Radio frequency circuit 1040 communicates with antennas 1050 and digital circuit 1030. In some embodiments, RF circuit 1040 includes a physical interface (PHY) corresponding to a communications protocol. For example, RF circuit 1040 may include modulators, demodulators, mixers, frequency synthesizers, low noise amplifiers, power amplifiers, and the like. In some embodiments, RF circuit 1040 may include a heterodyne receiver and, in other embodiments, RF circuit 1040 may include a direct conversion receiver. In some embodiments, RF circuit 1040 may include multiple receivers. For example, in embodiments with multiple antennas 1050, each antenna may be coupled to a corresponding receiver. In operation, RF circuit 1040 receives communications signals from antennas 1050, and provides signals to digital circuit 1030. Further, digital circuit 1030 may provide signals to RF circuit 1040, which operates on the signals and then transmits them to antennas 1050.

Digital circuit 1030 is coupled to communicate with processor 1010 and RF circuit 1040. In some embodiments, digital circuit 1030 includes circuitry to perform error detection/correction, interleaving, coding/decoding, or the like. Also, in some embodiments, digital circuit 1030 may implement all or a portion of a media access control (MAC) layer of a communications protocol. In some embodiments, a MAC layer implementation may be distributed between processor 1010 and digital circuit 1030.

Radio frequency circuit 1040 may be adapted to receive and demodulate signals of various formats and at various frequencies. For example, RF circuit 1040 may be adapted to receive time domain multiple access (TDMA) signals, code domain multiple access (CDMA) signals, global system for mobile communications (GSM) signals, orthogonal frequency division multiplexing (OFDM) signals, multiple-input-multiple-output (MIMO) signals, spatial-division multiple access (SDMA) signals, or any other type of communications signals. The present invention is not limited in this regard.

Antennas 1050 may include one or more antennas. For example, antennas 1050 may include a single directional antenna or an omni-directional antenna. As used herein, the term omni-directional antenna refers to any antenna having a substantially uniform pattern in at least one plane. For example, in some embodiments, antennas 1050 may include a single omni-directional antenna such as a dipole antenna or a quarter wave antenna. Also, for example, in some embodiments, antennas 1050 may include a single directional antenna such as a parabolic dish antenna or a Yagi antenna. In still further embodiments, antennas 1050 may include multiple physical antennas. For example, in some embodiments, multiple antennas are utilized to support multiple-input-multiple-output (MIMO) processing or spatial-divisional multiple access (SDMA) processing.

Memory 1025 represents an article that includes a machine readable medium. For example, memory 1025 represents a random access memory (RAM), dynamic random access memory (DRAM), static random access memory (SRAM), read only memory (ROM), flash memory, or any other type of article that includes a medium readable by processor 1010. Memory 1025 may store instructions for performing the execution of the various method embodiments of the present invention.

In operation, processor 1010 reads instructions and data from either or both of non-volatile memory 1020 and memory 1025 and performs actions in response thereto. For example, processor 1010 may access instructions from memory 1025 and program threshold voltages within reference voltage generators and reference current generators inside non-volatile memory 1020. In some embodiments, non-volatile memory 1020 and memory 1025 are combined into a single memory device. For example, non-volatile memory 1020 and memory 1025 may both be included in a single non-volatile memory device.

Although the various elements of system 1000 are shown separate in FIG. 3, embodiments exist that combine the circuitry of processor 1010, non-volatile memory 1020, memory 1025, and digital circuit 1030 in a single integrated circuit. For example, memory 1025 or non-volatile memory 1020 may be an internal memory within processor 1010 or may be a microprogram control store within processor 1010. In some embodiments, the various elements of system 1000 may be separately packaged and mounted on a common circuit board. In other embodiments, the various elements are separate integrated circuit dice packaged together, such as in a multi-chip module, and, in still further embodiments, various elements are on the same integrated circuit die.

The type of interconnection between processor 1010 and non-volatile memory 1020 is not a limitation of the present invention. For example, bus 1015 may be a serial interface, a test interface, a parallel interface, or any other type of interface capable of transferring command and status information between processor 1010, non-volatile memory 1020, and memory 1025.

Step voltage generators, voltage references, flash cells, and other embodiments of the present invention can be implemented in many ways. In some embodiments, they are implemented in integrated circuits. In some embodiments, design descriptions of the various embodiments of the present invention are included in libraries that enable designers to include them in custom or semi-custom designs. For example, any of the disclosed embodiments can be implemented in a synthesizable hardware design language, such as VHDL or Verilog, and distributed to designers for inclusion in standard cell designs, gate arrays, or the like. Likewise, any embodiment of the present invention can also be represented as a hard macro targeted to a specific manufacturing process. For example, memory array (FIG. 1) can be represented as polygons assigned to layers of an integrated circuit.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
using the output of a sense amplifier in a multiple-level non-volatile memory to reduce a supply voltage to a selected cell's bitline.

2. The method of claim 1 including using the output of a sense amplifier to turn off the supply voltage to a selected cell's bitline after sensing a cell on said bitline.

3. The method of claim 2 including inverting the output of the sense amplifier and providing the inverted output to control a switch.

4. The method of claim 3 including using a P-channel transistor as said switch, the source of said P-channel transistor coupled to a supply voltage.

5. The method of claim 1 including using the output of a sense amplifier in a flash memory.

6. The method of claim 5 including selectively applying one of at least three different voltages to a gate of a flash memory cell.

7. The method of claim 1 including maintaining the power to a word line of the selected cell after said supply voltage to the bitline is reduced.

8. A non-volatile memory comprising:
an array of non-volatile memory cells;
at least one comparator to detect the state of at least one of said cells; and
a switch coupled to the output of said comparator to reduce the voltage to said at least one cell after the state of said cell is detected.

9. The memory of claim 8 wherein said memory is a flash memory.

10. The memory of claim 8 including an inverter coupled to the output of said comparator.

11. The memory of claim 10 including a P-channel transistor whose gate is coupled to the output of said inverter and whose source is coupled to a supply voltage.

12. The memory of claim 8 including a multiplexer coupled to said at least one cell, said multiplexer to selectively apply one of at least two voltages to said at least one cell.

13. The memory of claim 12, said multiplexer to selectively apply one of at least three different voltages to a gate of said at least one cell.

14. The memory of claim 8, said at least one cell coupled to a word line and a bitline, said switch to reduce the voltage on the bitline.

15. The memory of claim 14 wherein power is maintained to the word line after said switch reduces to voltage to a cell's bitline.

16. A system comprising:
a processor;
a wireless interface coupled to said processor; and
a non-volatile memory coupled to said processor, said non-volatile memory including a plurality of memory cells, a sense amplifier to sense the state of at least one of said cells and a switch coupled to the output of said sense amplifier to turn off the voltage to a cell after the state of that cell has been sensed.

17. The system of claim 16 wherein said memory is a flash memory.

18. The system of claim 16, said memory including an inverter coupled to the output of said sense amplifier.

19. The system of claim 18, said memory including a P-channel transistor whose gate is coupled to the output of said inverter and whose source is coupled to a supply voltage.

20. The system of claim 16, said memory including a multiplexer coupled to said at least one cell, said multiplexer to selectively apply one of at least two voltages to said at least one cell.

21. The system of claim 20, said multiplexer to selectively apply one of at least three different voltages to a gate of a flash memory cell.

22. The system of claim 16, said selected cell coupled to a word line and a bitline, said switch to reduce the voltage on the bitline.

23. The system of claim 22 wherein power is maintained to the word line after said switch reduces to voltage to a cell's bitline.
